(19) United States
(12) Patent Application Publication
(10) Pub. No.: US 2025/0183135 A1
(43) Pub. Date: Jun. 5, 2025

(54) LEAD STABILIZATION IN SEMICONDUCTOR PACKAGES

(71) Applicant: STMICROELECTRONICS, INC., Calamba City (PH)

(72) Inventors: Ela Mia CADAG, Calamba City (PH); Frederick Ray GOMEZ, Calamba City (PH); Aaron CADAG, Calamba City (PH)

(73) Assignee: STMICROELECTRONICS, INC., Calamba City (PH)

(21) Appl. No.: 19/000,420

(22) Filed: Dec. 23, 2024

Related U.S. Application Data
(62) Division of application No. 16/848,635, filed on Apr. 14, 2020, now Pat. No. 12,211,774.
(60) Provisional application No. 62/838,814, filed on Apr. 25, 2019.

(51) Int. Cl. H01L 23/498; H01L 21/48; H01L 23/00

(52) U.S. Cl. CPC H01L 23/49811; H01L 21/4828; H01L 23/49838; H01L 24/45

(57) ABSTRACT

Generally described, one or more embodiments are directed to semiconductor packages comprising a plurality of leads and methods of forming same. The plurality of leads include active leads that are electrically coupled to bond pads of a semiconductor die and thereby coupled to active components of the semiconductor die, and inactive leads that are not electrically coupled to bond pads of the semiconductor die. The active leads have surfaces that are exposed at a lower surface of the semiconductor package and forms lands, while the inactive leads are not exposed at the lower surface of the package.

### BACKGROUND

### Technical Field

Embodiments of the present disclosure are directed to semiconductor packages and methods of assembling same.

### Description of the Related Art

Leadless (or no lead) packages are often utilized in applications in which small sized packages are desired. Typically, the flat leadless packages provide a near chip scale encapsulated package formed from a planar leadframe. Lands located on a lower surface of the package provide electrical connection to another device, such as a printed circuit board (PCB). Leadless packages, such as quad flat no-lead (QFN) packages, include a semiconductor die or chip mounted to a support surfaces of a leadframe, such as a die pad or ends of leads. The semiconductor die is electrically coupled to the leads, often by conductive wires.

The process of wire bonding the conductive wires may involve heat and ultrasonic energy. Due to instability of the leads, a bouncing effect may occur while the conductive wires are bonded to the leads. The bouncing effect may be exacerbated by the ultrasonic energy that is introduced during the bonding process and may result in a weaker bond between the lead and the conductive wire. Thus, improvements are desired.

### BRIEF SUMMARY

Generally described, one or more embodiments are directed to semiconductor packages comprising a plurality of leads and methods of forming same. The plurality of leads include active leads that are electrically coupled to bond pads of a semiconductor die and thereby coupled to active components of the semiconductor die, and inactive leads that are not electrically coupled to bond pads of the semiconductor die. The active leads have surfaces that are exposed at a lower surface of the semiconductor package and forms lands, while the inactive leads are not exposed at the lower surface of the package. In one or more embodiments, the inactive leads provide additional stabilization during assembly, such as during die attach and wire bond processing.

The inactive leads have a reduced thickness relative to at least a portion of the active leads. In one embodiment, the inactive leads are half etched and only portions of the active leads are half etched. The entire thickness of each inactive lead is less than at least a portion of a thickness of the active leads. Both the inactive leads and the active leads may be exposed at side surfaces of the semiconductor packages. In at least one embodiment, the leads are formed from a leadframe and are symmetrically arranged about at least one axis of the leadframe, such as a central axis.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale.

FIG. 1A is shows a top isometric view of a semiconductor package according to one embodiment.

FIG. 1B is a bottom view of the semiconductor package of FIG. 1A.

FIG. 1C is a side view of the semiconductor package of FIG. 1A.

FIG. 2A is a top view of a leadframe array for forming the semiconductor package of FIG. 1A according one embodiment.

FIG. 2B is a bottom view of the leadframe array of FIG. 2A.

FIG. 3A is a top view of an individual leadframe of the leadframe array of FIG. 2A.

FIG. 3B is a bottom view of an individual leadframe of the leadframe array of FIG. 2B.

FIGS. 4A-4F are cross-sectional views of the semiconductor package of FIG. 1A at various stages of assembly.

### DETAILED DESCRIPTION

Generally described, one or more embodiments are directed to semiconductor packages comprising a plurality of leads and methods of forming same. The plurality of leads include active leads that are electrically coupled to bond pads of a semiconductor die and thereby coupled to active components of the semiconductor die, and inactive leads that are not electrically coupled to bond pads of the semiconductor die. The active leads have surfaces that are exposed at a lower surface of the semiconductor package and forms lands, while the inactive leads are not exposed at the lower surface of the package. In one or more embodiments, the inactive leads provide additional stabilization during assembly, such as during die attach and wire bond processing.

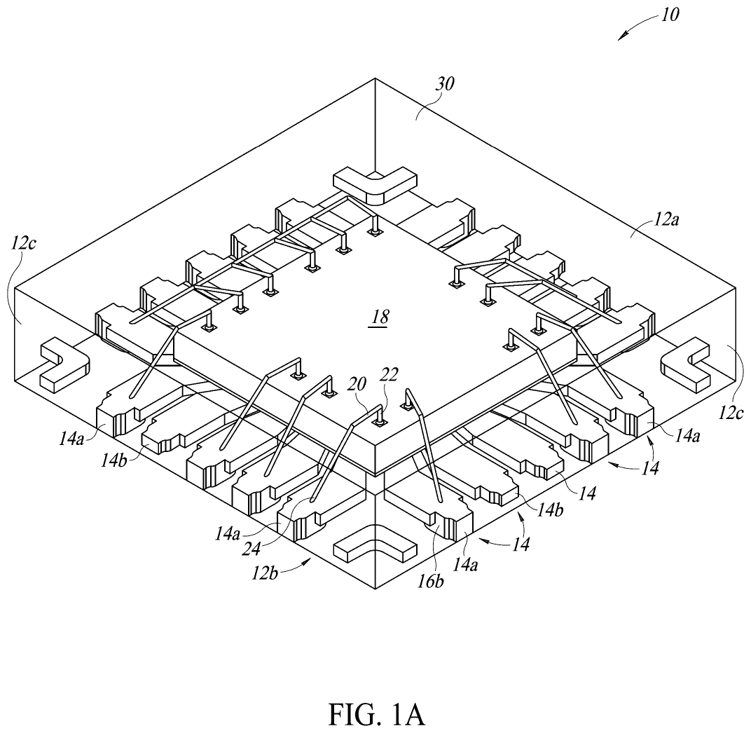

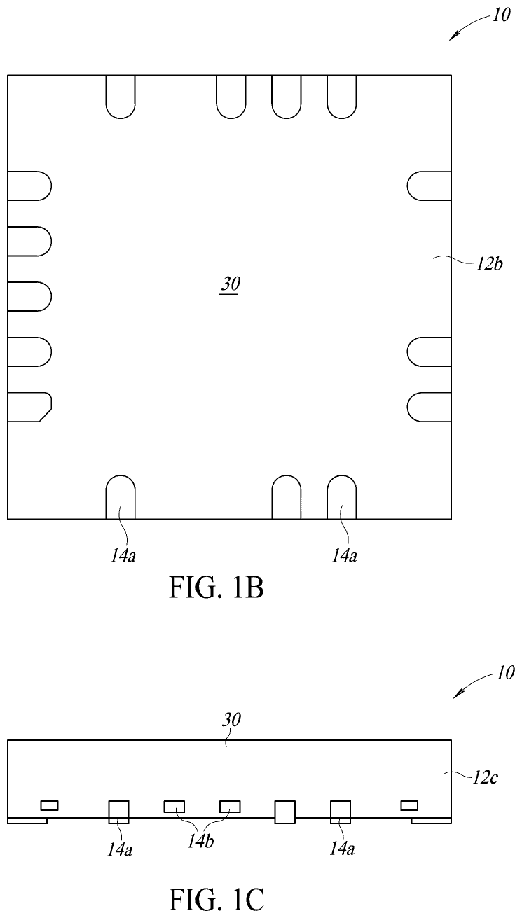

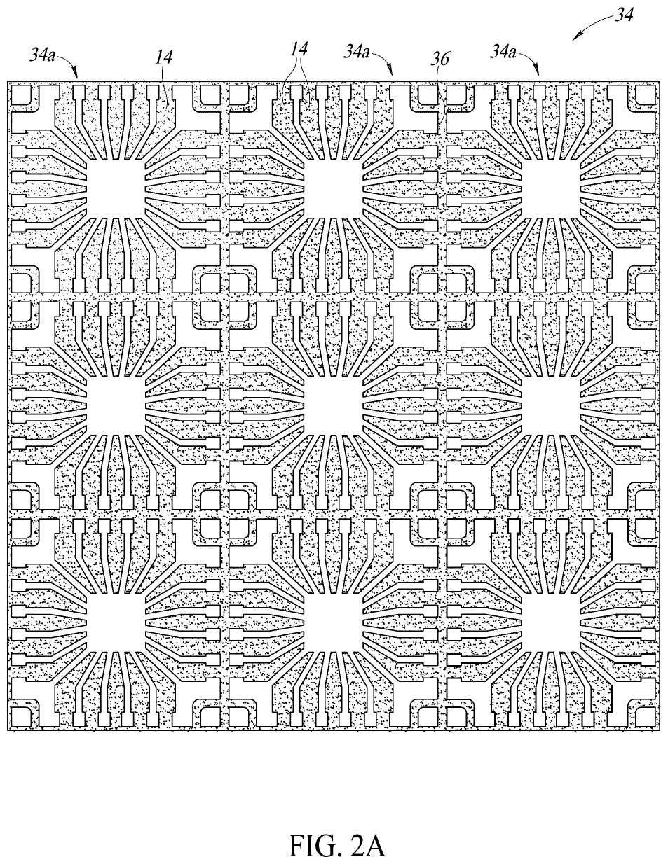

FIG. 1A shows an isometric view of a semiconductor package 10 in accordance with one embodiment. The semiconductor package 10 is a chip-on-lead (COL) semiconductor package. FIG. 1B is a bottom view of the semiconductor package 10, and FIG. 1C is a side view of the semiconductor package 10.

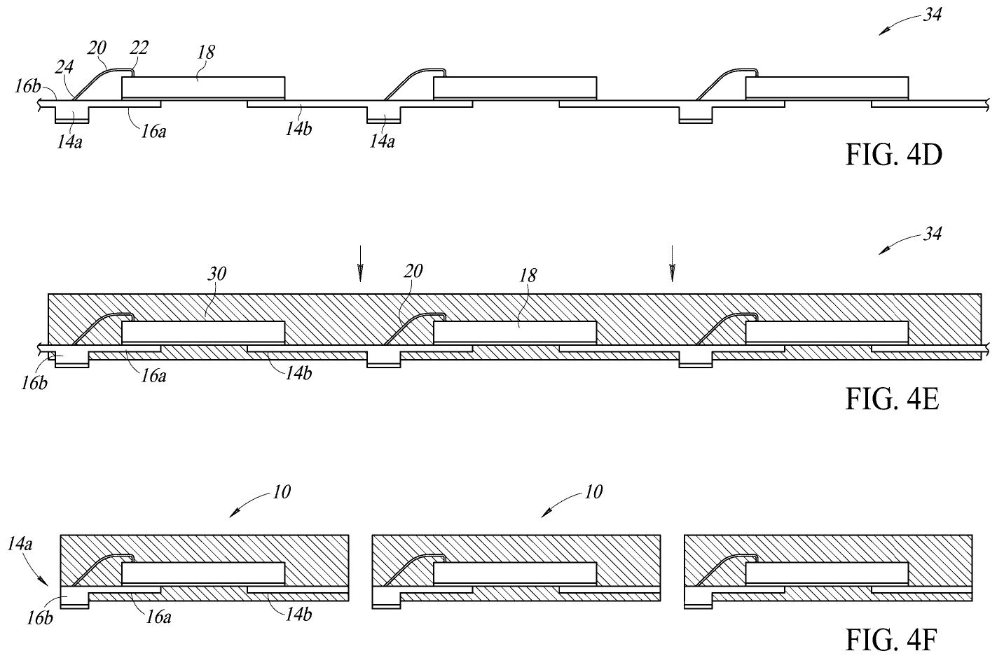

The semiconductor package 10 includes an upper surface 12a, a lower surface 12b, and side surfaces 12c. The semiconductor package 10 includes a plurality of leads 14 having inner portions 16a (FIG. 4C) that support a semiconductor die or chip 18 and outer portions 16b that extend to the side surfaces 12c of the semiconductor package 10.

The semiconductor die 18 is made from semiconductor material, such as silicon, and includes an active surface integrating one or more electrical components, such as integrated circuits. The active surface of the semiconductor die 18 includes conductive bond pads that are electrically connected to one or more of the electrical components.

The semiconductor die 18 is coupled to the inner portions 16a of the plurality of leads 14 by a material configured to hold the semiconductor die 18 in place during assembly. In one embodiment, the semiconductor die 18 is coupled to the inner portions 16a of the plurality of leads 14 by an adhesive material, such as glue, paste, tape and the like. In other embodiments, the semiconductor die 18 is coupled to a die pad (not shown) that supports the semiconductor die and the plurality of leads are located around and spaced apart from the die pad as is well known in the art.

The plurality of leads 14 may be symmetrically arranged about one or more axes and may be symmetrically arranged about an axis of the semiconductor die 18. The plurality of leads 14 includes both active leads 14a and inactive leads 14b.

Although the semiconductor die 18 is coupled to both the active leads 14a and the inactive leads 14b for support, the active surface of the semiconductor die 18 is electrically coupled only to the active leads 14a. In particular, the bond pads of the semiconductor die 18 are electrically coupled to surfaces of the active leads 14a by conductive wires 20, respectively. For example, a first end 22 of a conductive wire 20 is coupled to a bond pad of the semiconductor die 18, and a second end 24 of the conductive wire 20 is coupled to a first surface of the active lead 14a.

As previously mentioned, the inactive leads 14b of the plurality of leads 14 are not electrically coupled to the active surface of the semiconductor die 18. Thus, the active leads 14a are electrically coupled to the integrated circuits of the active surface of the semiconductor die 18, while the inactive leads 14b are electrically decoupled from the integrated circuits of the active surface of the semiconductor die 18.

In other embodiments, the active surface of the semiconductor die 18 may be electrically coupled to the active leads 14a by other techniques, such as flip chip as is well known in the art. In such an embodiment, the semiconductor die is flipped over and faces the leads and conductive bumps are located between the active leads and the bond pads of the semiconductor die.

A package body 30 covers the semiconductor die 18 and the conductive wires 20 and portions of the leads 14. The package body 30 is an insulating material, such as an encapsulation material, that protects the electrical components of the semiconductor die and conductive wires from damage, such as corrosion, physical damage, moisture damage, or other causes of damage to electrical devices and materials. In some embodiment, the package body 30 is at least one of a polymer, silicone, resin, polyimide, and epoxy. The package body 30 is shown in FIG. 1A as transparent so that inner details of the semiconductor package 10 can be readily seen. The package body is, however, typically made of an opaque material.

With reference to FIG. 1B, the active leads 14a have second surfaces that are exposed from the package body 30 at the lower surface 12b of the semiconductor package 10 to form lands. Remaining portions of the active leads 14a are covered by the package body 30. The inactive leads 14b are not exposed from the package body 30 at the lower surface 12b of the semiconductor package 10 as best shown in FIG. 1B. Rather, the package body 30 covers the inactive leads 14b at the lower surface.

With reference to FIG. 1C, both the inactive leads 14b and the active leads 14a have surfaces that are exposed at side surfaces 12c of the semiconductor package 10. The surfaces of the inactive leads 14b and the active leads 14a may be flush with a surface of the package body 30. The surfaces of the active leads 14a extend along the respective side surface 12c of the semiconductor package 10 to the lower surface 12b of the semiconductor package 10, while the surfaces of the inactive leads 14b do not extend to the lower surface 12b of the semiconductor package 10. That is, the package body 30 is between the exposed surfaces of the inactive leads 14b and the lower surface 12b of the semiconductor package 10. As previously mentioned, the package body 30 covers surfaces of the inactive leads 14b at the lower surface 12b of the semiconductor package 10 so that surfaces of the inactive leads 14b are not exposed at the lower surface 12b of the semiconductor package 10.

As best shown in FIG. 1C, thicknesses of the active leads 14a and inactive leads 14b are different from each other. In at least one embodiment, the inactive leads 14b have a thickness that is about one half, such as between 40% to 60%, the thickness of the outer portions of the active leads 14a. As will be explained in more detail below, the inactive leads 14b provide stability during assembly of the semiconductor package 10. In at least one embodiment, the inactive leads 14b and the active leads 14a provide suitable support for the semiconductor die 18 during wire bonding.

The number and combination of active leads 14a may be different than is shown. Any number or combination of active leads 14a may be selected, including active leads being located along two sides, such as opposing sides, or along only one side of the semiconductor package. In general, which leads 14 are to be active leads 14a is determined by the application for the semiconductor package, typically based on customer specifications.

The active leads 14a have first and second thicknesses. The first thickness is at the inner portions 16a of the active leads 14a and the second thickness is at the outer portions 16b of the active leads 14a, which is best shown in FIG. 4F. The first thickness is less than the second thickness. In some embodiments, the first thickness is between 40% and 60%, and in one embodiment about 50%, the second thickness. As previously mentioned, the lower surfaces of the outer portions 16b of the active leads 14a form lands for coupling the semiconductor package to another device.

The inactive leads 14b have a constant thickness, which may be the same thickness as the first thickness of the active leads. The outer portions 16b of the inactive leads 14b have the first thickness, while the outer portions 16b of the active leads 14a have the second thickness, which is greater than the first thickness. The package body 30 covers the lower surfaces of the inactive leads 14b and the portions of the active leads 14a having the first thicknesses.

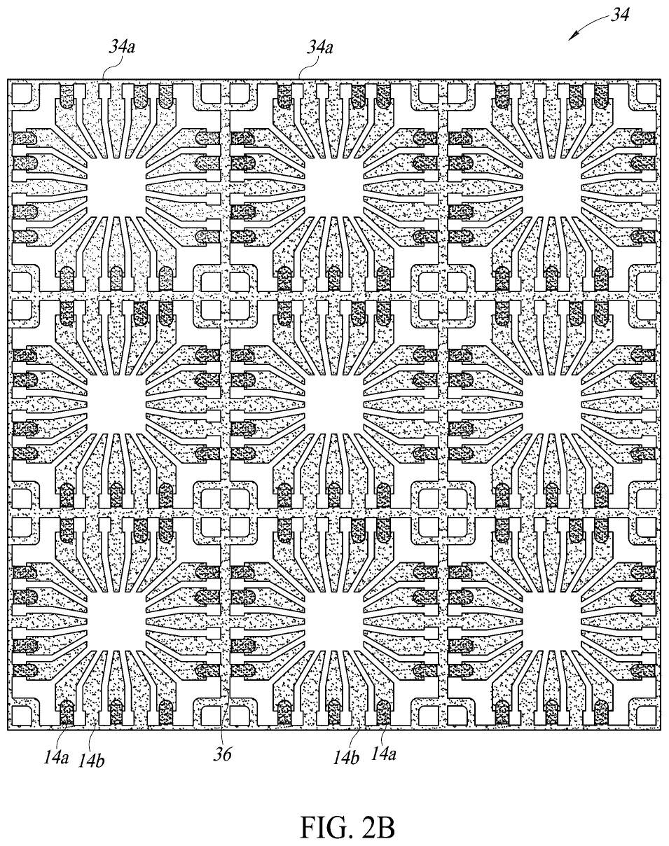

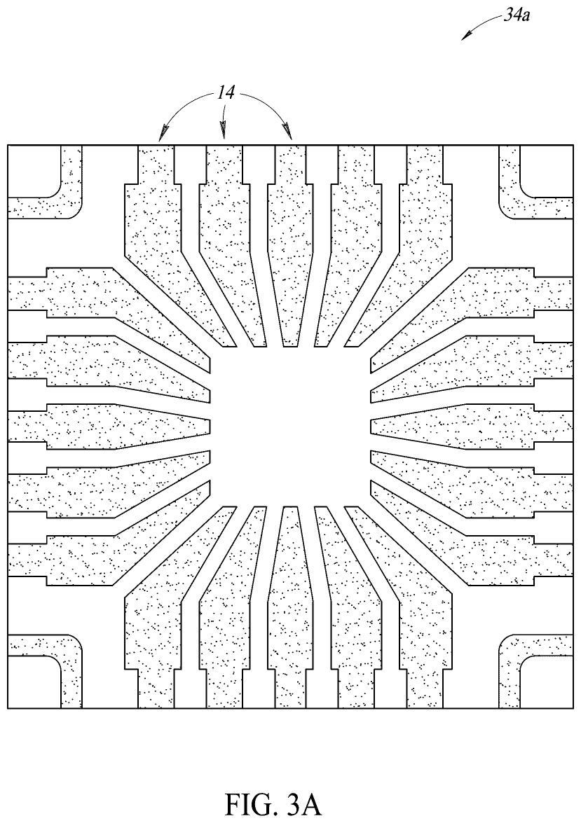

FIG. 2A shows an upper surface of a leadframe array 34 used for forming semiconductor packages, such as the semiconductor package 10 of FIGS. 1A-1C, according one embodiment. FIG. 2B shows a lower surface of the leadframe array 34 of FIG. 2A. The leadframe array 34 is made of conductive material, such as a metal. In at least one embodiment the leadframe array 34 is made of copper or a copper alloy. The leadframe 34 is shown with stippling to provide clarity as to which portions form the leadframe and which portions do not form the leadframe, and to show depth. In particular, the bottom view of the leadframe 34 includes thicker stippling to indicate thicker portions of the leadframe 34.

The leadframe array 34 includes a plurality of individual leadframes 34a arranged in columns and rows, each for forming a respective semiconductor package. The leads 14 of adjacent individual leadframes 34a are coupled together by connecting bars 36. In at least one embodiment, the leads 14 are arranged in a symmetrical arrangement about one or more axes, such as a central axis, of the individual leadframes 34a.

During assembly, the leads 14 of adjacent individual leadframes 34a provide suitable stabilization of any active leads during the wire bonding process. Active leads of adjacent individual leadframes may oppose each other at the connecting bars 36 or an inactive lead may oppose an active lead. Furthermore, by providing more leads than are used as active leads in the final semiconductor package, the assembly of the package is improved. In particular, the inactive leads provide stability during the wire bonding process.

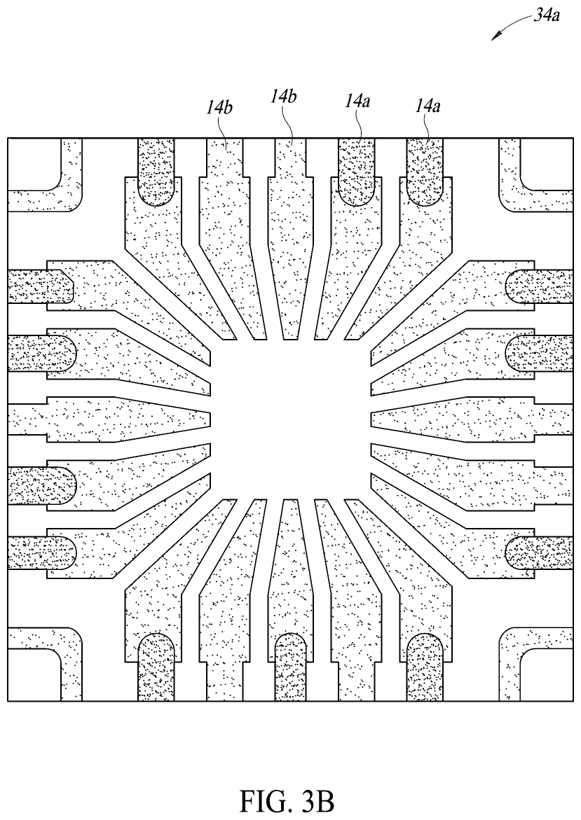

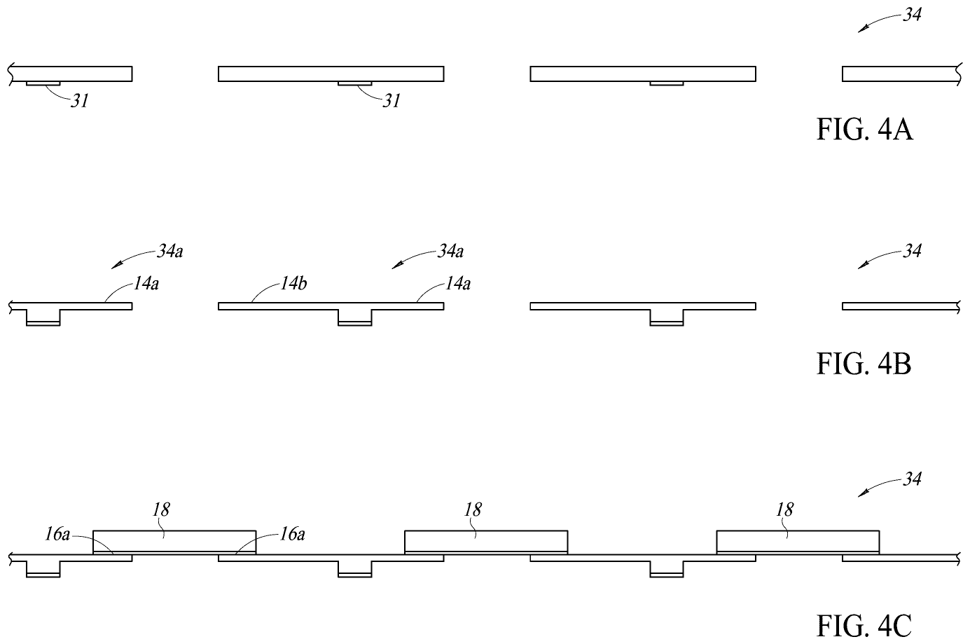

FIGS. 3A and 3B show close up views of the upper and lower surfaces, respectively, of an individual leadframe 34a. With reference to FIG. 3A, the upper surfaces of the leads 14, including active leads and inactive leads, of the individual leadframe 34 are in a same plane as indicated by the same volume of stippling. With reference to FIG. 3B, the lower surfaces of the inactive leads 14b and first portions of the active leads 14a of the individual leadframe 34 are in a same plane as indicated by the same volume of stippling. Outer portions of the active leads 14a are in a different plane as indicated by the increased volume of stippling. In particular, the outer portions of the active leads 14a are thicker and have surfaces in a plane that extends out of the page, relative to the inner portions of the active leads 14a.

FIGS. 4A and 4B illustrate various stages of manufacturing the leadframe array 34 of FIGS. 2A and 2B. The leadframe array 34 of FIG. 4A already has leads, however, the inactive leads have not yet been formed.

As shown in FIG. 4A, outers portions of the active leads 14a that are to form lands 31 of the active leads 14a are covered with a material so that the rest of the leads may be etched. In one embodiment, the active leads 14a are plated with one or more metal materials, such as Au, Ag, Ni/Pd/Ag, Ni/Pd/Au—Ag alloy, or Ni/Pd/Au/Ag, which thereby form the lands of the active leads 14a. In another embodiment, the outer portions of the active leads 14a are patterned with light sensitive materials as is well known in the art.

With reference to FIG. 4B, lower surfaces of the leads 14, of both the active leads 14a and inactive leads 14b, are etched using standard semiconductor etching techniques. In particular, inner portions of the active leads 14 are etched that do not include plated metal material or light sensitive material and entire surfaces of the inactive leads 14b are etched. The etching occurs to a depth of about one half the original thickness of the leadframe, also referred to as half etched. In one embodiment, the etching occurs to about 50% the original thicknesses of the leads. In other embodiments, the etching occurs to between 40% to 60% of the original thicknesses of the leads. After etching, each individual leadframe 34a of the leadframe array 34 includes an active lead 14a and an inactive lead 14b as shown in FIG. 1B.

FIGS. 4C-4F illustrate various stages of assembling the semiconductor package of FIG. 1A in accordance with one embodiment. In particular, as shown in FIG. 4C, semiconductor dice 18 are coupled to inner portions 16a of the leads 14. In particular, the semiconductor dice 18 are coupled to inner portions 16a of the active leads 14a and inactive leads 14b. By providing both active leads 14a and inactive leads 14b for supporting each semiconductor die 18, the supporting structure for the semiconductor die is improved. Further, the symmetrical arrangement of the plurality of leads provides improved support for the semiconductor dice 18 during dice attachment. Additionally, leads of adjacent individual leadframes 34a are coupled together by connecting bars 36 and are able to provide improved support to each other during dice attachment.

With reference to FIG. 4D, the semiconductor dice 18 are electrically coupled to the active leads 14a in a bonding process. In particular, first ends 22 of conductive wires 20 are coupled to bond pads of the semiconductor die 18, and second ends 24 of the conductive wires 20 are coupled to outer portions 16b of the active leads 14a. The bonding process of coupling the conductive wires 20 may involve heat and ultrasonic energy. Although only one conductive wire is shown for each individual leadframe, it is to be understood that conductive wires are being coupled to other active leads and bond pads of the semiconductor dice not shown in FIG. 4D.

During the bonding process of coupling the conductive wires 20 to the active leads 14a, all of the leads 14, both the active leads 14a and the inactive leads 14b, provide stabilization. For instance, while ultrasonic energy is being applied during the bonding process, the stability of the leadframe that is created in part by the inactive leads, eliminates or reduces any bouncing effect the ultrasonic energy may introduce. In that regard, stronger bonds may be provided between the active leads 14a and the conductive wires 20.

As previously mentioned the quantity and location of active leads may be identified by a particular application for the semiconductor package, such as by a customer. However, the number of inactive leads may be selected by the amount of stabilization that is desired during manufacturing.

As shown in FIG. 4E, a package body 30 is formed on the semiconductor dice 18, the conductive wires 20, and portions of the plurality of leads 14 to form semiconductor packages. In at least one embodiment, the package body 30 is formed in a mold. In particular, the leadframe array 34 is placed in a mold and molding material, such as a resin, is introduced into the mold, as is well known in the art. In at least one embodiment, the molding material hardens in a curing step to form the package body 30.

As shown in FIG. 4E, the package body 30 forms over upper and lower surfaces of the inactive leads 14b. Outer portions 16b of the active leads 14a remain exposed from the package body 30 to form lands, while inner portions 16a of the active leads 14a at the lower surface are covered by the package body 30.

The assembly process further includes separating the semiconductor packages into individual packages 10. In particular, the dicing occurs at locations as indicated by the arrows as shown in FIG. 4E and separates the connected semiconductor packages into individual semiconductor packages 10 as shown in FIG. 4F. The dicing cuts through the connecting bars 36, the package body 30, and the leads to separate the semiconductor packages 10. The dicing method may be any method suitable to separate the semiconductor packages, including sawing and laser. Although not shown, the connected semiconductor packages may be secured to a support structure, such as tape, during the dicing step, as is well known in the art.

Upon dicing side surfaces of both the active and inactive leads 14a, 14b are exposed at the side surface of the individual semiconductor packages as shown in FIG. 1C.

The stages of manufacturing and assembly may occur in a different order as well. For instance, the leads may be half etched after the semiconductor die is coupled to the leadframe. Further, although the embodiments shown in the figures show the leads supporting the semiconductor, in other embodiments, the leadframe package includes a die pad that supports the semiconductor die.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
coupling a semiconductor die to a plurality of leads;
electrically coupling bond pads of the semiconductor die to a first set of the plurality of leads to form a plurality of active leads, wherein a second set of the plurality of leads remains decoupled from bond pads of the semiconductor die and forms a plurality of inactive leads; and
forming a package body over the semiconductor die and portions of the plurality of leads.

2. The method of claim 1, wherein electrically coupling comprises coupling first ends of conductive wires to the bond pads of the semiconductor die and coupling second ends of the conductive wires to the active leads.

3. The method of claim 1, wherein a surface of a lead of the plurality of leads is exposed from the package body at a side surface of the package body.

4. The method of claim 3, wherein surfaces of the plurality of inactive leads are covered by the package body at a bottom surface of the package body, and wherein lands of the plurality of active leads are exposed from the package body at the bottom surface.

5. The method of claim 1, wherein prior to coupling the semiconductor die to the plurality of leads, the plurality of inactive leads are etched.

6. The method of claim 5, wherein prior to coupling the semiconductor die to the plurality of leads, inner portions of the plurality of active leads are etched.

7. The method of claim 1, wherein forming the package body comprises using a mold to introduce a molding material to form the package body.

8. A method of manufacturing a semiconductor package, comprising:
coupling a back surface of a semiconductor die to a plurality of leads;
coupling a conductive wire to a bond pad on an active surface of the semiconductor die opposite to the back surface;
coupling the conductive wire to an active lead of the plurality of leads; and
covering the semiconductor die, the conductive wire, and at least a portion of the plurality of leads with a package body, including arranging the package body such that at least one inactive lead of the plurality of leads extends through the package body and terminates coplanar with at least a portion of an outer surface of the package body.

9. The method of claim 8, further comprising at least one of:
electrically isolating the active surface of the semiconductor die from the at least one inactive lead, and
electrically isolating the at least one inactive lead from an active surface of any other semiconductor dice in the semiconductor package.

10. The method of claim 8, wherein covering the semiconductor die includes arranging the package body such that an outer end of the at least one inactive lead is exposed at the at least the portion of the outer surface of the package body.

11. The method of claim 8, wherein coupling the back surface of the semiconductor die includes spacing at least a portion of the back surface of the semiconductor die from an inner end of the active lead.

12. The method of claim 8, wherein coupling the back surface of the semiconductor die includes attaching a back surface of the semiconductor die to an adhesive layer on the at least one inactive lead.

13. The method of claim 12, wherein attaching the back surface of the semiconductor die to the adhesive layer includes spacing the back surface of the semiconductor layer from the at least one inactive lead by only the adhesive layer.

14. A method of manufacturing a semiconductor package, comprising:
applying an adhesive layer to a plurality of inactive leads of a plurality of leads;
coupling a back surface of a semiconductor die to the adhesive layer, including separating the back surface of the semiconductor die from the plurality of inactive leads by the adhesive layer; and
arranging a package body on the semiconductor die and at least a portion of the plurality of leads, including arranging the package body such that the plurality of inactive leads extend through the package body and outer ends of the plurality of inactive leads terminate coplanar with, and are exposed at least in part at, an outer side surface of the package body.

15. The method of claim 14, further comprising at least one of:
electrically isolating an active surface of the semiconductor die from the plurality of inactive leads, and
electrically isolating the plurality of inactive leads from an active surface of any other semiconductor dice in the semiconductor package.

16. The method of claim 14, wherein arranging the package body includes arranging the package body such that outer ends of a plurality of active leads of the plurality of leads extend from the package body.

17. The method of claim 14, wherein applying the adhesive layer includes applying the adhesive layer directly on the plurality of inactive leads.

18. The method of claim 17, wherein coupling the back surface of the semiconductor die includes coupling the back surface of the semiconductor die directly to the adhesive layer.

19. The method of claim 14, further comprising:
coupling a conductive wire to an active lead of the plurality of leads and to a bond pad on an active surface of the semiconductor die.

20. The method of claim 14, wherein coupling the back surface of the semiconductor die includes spacing at least a portion of the back surface of the semiconductor die from an inner end of an active lead of the plurality of leads.
